(19) United States
(12) Patent Application Publication
(10) Pub. No.: US 2019/0058024 A1
(43) Pub. Date: Feb. 21, 2019

(54) ORGANIC LIGHT EMITTING DIODE DISPLAY PANEL AND METHOD FOR MANUFACTURING SAME

(71) Applicant: SHENZHEN CHINA STAR OPTOELECTRONICS SEMICONDUCTOR DISPLAY TECHNOLOGY CO., LTD., Shenzhen, Guangdong (CN)

(72) Inventors: Weijing ZENG, Shenzhen, Guangdong (CN); Baixiang HAN, Shenzhen, Guangdong (CN)

(73) Assignee: SHENZHEN CHINA STAR OPTOELECTRONICS SEMICONDUCTOR TECHNOLOGY CO., LTD., Shenzhen, Guangdong (CN)

(21) Appl. No.: 15/577,077

(22) PCT Filed: Oct. 19, 2017
(86) PCT No.: PCT/CN2017/106785

§ 371 Date: Nov. 27, 2017

(30) Foreign Application Priority Data
Aug. 21, 2017 (CN) 201710717933.6

(51) Int. Cl. H01L 27/32; H01L 51/52; H01L 51/56; H01L 27/12

(52) U.S. Cl. CPC H01L 27/3258; H01L 51/5206; H01L 27/1214; H01L 51/56; H01L 51/5221

(57) ABSTRACT

An organic light emitting diode (OLED) display panel and a method for manufacturing the OLED display panel are provided. The OLED display panel includes a first electrode layer, a second insulating layer, and an auxiliary electrode layer. The first electrode layer includes a plurality of first electrodes. The second electrode layer includes a plurality of second electrodes. The first electrodes and the second electrodes are aligned with each other. The auxiliary electrode layer includes rows of auxiliary electrode, each row of the auxiliary electrodes is corresponding to and electrically connected with a row of the second electrodes.

### FIELD OF THE INVENTION

This disclosure relates to display technology, and more particularly to an organic light emitting diode display panel and a method for manufacturing the organic light emitting diode display panel.

### BACKGROUND OF THE INVENTION

Organic light-emitting diodes (OLEDs) have characteristics of self-luminosity, high brightness, wide viewing angles, high contrast, flexible, low energy consumption, and other characteristics. So it has received widespread attention and is widely used in mobile phone screens, computer monitors, full-HD TVs, etc., as a new generation of displays to gradually replace traditional LCDs.

Requirements of OLED top emission structure of cathodes are very high. The cathodes require both high transparency and good electrical conductivity. Conventional top emission OLED elements generally use whole Mg/Ag material, and an Mg/Ag work function is used for matching with organic materials, but cannot achieve effects of high transparency and high conductivity. It is because thickness of a metal layer is thinner, leading to worse conductivity. Flexible displays are the trend for future displays, and structure of entire cathode is prone to breakage due to stress.

Thus, it is necessary to provide an organic light emitting diode display panel and a method for manufacturing the organic light emitting diode display panel to solve problems of the prior art.

### SUMMARY OF THE INVENTION

The object of this disclosure is to provide an organic light emitting diode display panel and a method for manufacturing the organic light emitting diode display panel to achieve the cathode matching a work function of an organic material and further to achieve high transparency and high conductivity.

In order to solve the above-mentioned drawbacks, preferred embodiments of the disclosure provides an organic light emitting diode (OLED) display panel, which comprises a substrate, and a thin film transistor layer, a first insulating layer, a first electrode layer, a second insulating layer, a light emitting layer, a second electrode layer, a barrier layer, an auxiliary electrode layer, and a planarization layer arranged on the substrate in sequence.

The first electrode layer comprises a plurality of first electrodes arranged in an array, the second electrode layer comprises a plurality of second electrodes arranged in an array. The first electrodes and the second electrodes are aligned with each other, and the auxiliary electrode layer comprises rows of auxiliary electrodes, each row of the auxiliary electrodes is corresponding to and electrically connected with a row of the second electrodes.

The first insulating layer is provided with a first through hole, the second insulating layer is provided with a second through hole, and the barrier layer is provided with a third through hole.

The first electrode is in contact with the thin film transistor layer through the first through hole, the light emitting layer is in contact with the first electrode through the second through hole, and the auxiliary electrode is in contact with the second electrode through the third through hole.

A thickness of the second electrode layer is less than 2 nm.

In the OLED display panel of this disclosure, the auxiliary electrode layer is made of graphene.

In the OLED display panel of this disclosure, the barrier layer is made of silicon nitride, aluminum oxide or silicon oxide.

In the OLED display panel of this disclosure, a thickness of the planarization layer is between 1 μm to 5 μm.

In the OLED display panel of this disclosure, the second electrode layer is made of magnesium or silver.

In the OLED display panel of this disclosure, the OLED display panel further comprises at least one encapsulation layer disposed on the planarization layer, and each of the encapsulation layer comprises the barrier layer and the planarization layer that are laminated.

In order to solve the above-mentioned drawbacks, preferred embodiments of the disclosure further provides an organic light emitting diode (OLED) display panel, which comprises a substrate, and a thin film transistor layer, a first insulating layer, a first electrode layer, a second insulating layer, a light emitting layer, a second electrode layer, a barrier layer, an auxiliary electrode layer, and a planarization layer laminated on the substrate in sequence.

The first electrode layer comprises a plurality of first electrodes arranged in an array, the second electrode layer comprises a plurality of second electrodes arranged in an array. The first electrodes and the second electrodes are aligned with each other, and the auxiliary electrode layer comprises rows of auxiliary electrodes, each row of the auxiliary electrodes is corresponding to and electrically connected with a row of the second electrodes.

In the OLED display panel of this disclosure, the first insulating layer is provided with a first through hole, the second insulating layer is provided with a second through hole, and the barrier layer is provided with a third through hole. The first electrode is in contact with the thin film transistor layer through the first through hole, the light emitting layer is in contact with the first electrode through the second through hole, and the auxiliary electrode is in contact with the second electrode through the third through hole.

In the OLED display panel of this disclosure, the auxiliary electrode layer is made of graphene.

In the OLED display panel of this disclosure, the barrier layer is made of silicon nitride, aluminum oxide or silicon oxide.

In the OLED display panel of this disclosure, a thickness of the planarization layer is between 1 μm to 5 μm.

In the OLED display panel of this disclosure, the second electrode layer is made of magnesium or silver.

In the OLED display panel of this disclosure, a thickness of the second electrode layer is less than 2 nm.

In the OLED display panel of this disclosure, the OLED display panel further comprises at least one encapsulation layer disposed on the planarization layer, and each of the encapsulation layer comprises the barrier layer and the planarization layer that are laminated.

According to the above object of the disclosure, this disclosure further provides a method for manufacturing an organic light emitting diode (OLED) display panel, which comprises steps of:

providing a substrate and forming a thin film transistor layer on the substrate, wherein the substrate comprises a plurality of thin film transistors spaced from each other;

forming a first insulating layer on the thin film transistor layer and forming a first through hole corresponding to the thin film transistors on the first insulating layer, respectively;

forming a first electrode layer on the first insulating layer, wherein the first electrode layer comprises a plurality of first electrodes arranged in an array, the first electrodes and the thin film transistors are aligned with each other, and the first electrode is in contact with the thin film transistor layer through the first through hole;

forming a second insulating layer on the first electrode layer and forming a second through hole corresponding to the thin film transistor on the second insulating layer, respectively;

forming a light emitting layer on the second insulating layer, wherein the light emitting layer is in contact with the first electrode through the second through hole;

forming a second electrode layer on the light emitting layer, wherein the second electrode layer comprises a plurality of second electrodes arranged in an array, and the second electrodes and the first electrodes are aligned with each other;

forming a barrier layer on the second electrode layer and forming a third through hole corresponding to the thin film transistor on the barrier layer, respectively;

forming an auxiliary electrode layer on the barrier layer, wherein the auxiliary electrode layer comprises rows of auxiliary electrode, each row of the auxiliary electrodes is corresponding to a row of the second electrodes, and each of the auxiliary electrodes is connected with one of the second electrodes through the third through hole;

forming a planarization layer on the auxiliary electrode layer.

In the method for manufacturing an organic light emitting diode (OLED) display panel of this disclosure, after the step of forming the planarization layer on the auxiliary electrode layer, the method further comprises a step of forming at least one encapsulation layer on the planarization layer, wherein each of the encapsulation layer comprises the barrier layer and the planarization layer that are laminated.

This disclosure relates to the organic light emitting diode display panel and the method for manufacturing the organic light emitting diode display panel. The first electrode layer comprises a plurality of first electrodes arranged in an array. The second electrode layer comprises a plurality of second electrodes arranged in an array. The first electrodes and the second electrodes are aligned with each other. The auxiliary electrode layer comprises rows of auxiliary electrodes, each row of the auxiliary electrodes is corresponding to and electrically connected with a row of the second electrodes, thereby achieving the second electrode matching a work function of an organic material, and at the same time achieving high transparency and conductivity. The auxiliary electrodes can be graphene with high conductivity, high thermal conductivity, thereby effectively improving heat dissipation of the display panel, and reducing the packaging stress.

The preferred embodiments adopted by this disclosure are given in the following detailed description, with reference to the drawings.

### DESCRIPTION OF THE DRAWINGS

FIG. 1 is a layered structural schematic view of an organic light emitting diode display panel according to a preferred embodiment of this disclosure.

FIG. 2 is a layered structural schematic view of a light emitting layer.

FIG. 3 is a flowchart of a method for manufacturing the organic light emitting diode display panel according to a preferred embodiment of this disclosure.

### DETAILED DESCRIPTION OF THE PREFERRED EMBODIMENTS

The specific structural and functional details disclosed herein are merely representative and are intended to describe the purpose of the exemplary embodiments of this disclosure. This disclosure may be embodied in many and may not be construed as limited to the embodiments set forth herein.

In the description of this disclosure, it is to be understood that this description of the exemplary embodiments is intended to be read in connection with the accompanying drawings, which are to be considered part of the entire written description. In the description, terms such as “center”, “horizontal”, “lower”, “upper”, “left”, “right”, “horizontal”, “vertical”, “top”, “bottom”, “inside”, and “outside” as well as derivatives thereof should be construed to refer to the orientation as then described or as shown in the drawing under discussion. These terms are for convenience of description and do not require that the apparatus be constructed or operated in a particular orientation, and do not limit the scope of the disclosure. In addition, the terms “first” and “second” are for descriptive purposes only and are not to be construed as indicating or imposing relative importance or implicitly indicating the number of technical features indicated. Thus, a feature that defines the terms “first” and “second” may expressly or implicitly include one or more of the features. In the description of this disclosure, the meaning of “plural” is two or more, unless otherwise specified. In addition, the term “comprise” and any variations thereof are intended to cover non-exclusive inclusion.

In the description of this disclosure, it is to be understood that the terms “install”, “connected to”, “connect” should be broadly understood, unless otherwise specified and defined, for example, a fixed connection or a removable connection, or integrally connected, or a mechanical connection or an electrical connection. It can be directly connected or indirectly connected by an intermediate medium or it can be connected inside the two components. The specific meaning of the above-mentioned terms in this disclosure can be understood by those skilled in the art in specific circumstances.

The terms used herein is for the purpose of describing specific embodiments only and is not intended to limit the exemplary embodiments. Unless the context clearly dictates otherwise, the singular forms “a” and “an” as used herein, are also intended to include the plural. It should also be understood that the terms “comprising” and/or “including” used herein are to describe the presence of the features, integers, steps, operations, elements and/or components described herein, without excluding the presence or addition of one or more other features, integers, steps, operations, units, components, and/or combinations thereof.

Referring now in more detail to the drawings in which like numerals indicate corresponding parts throughout the drawings.

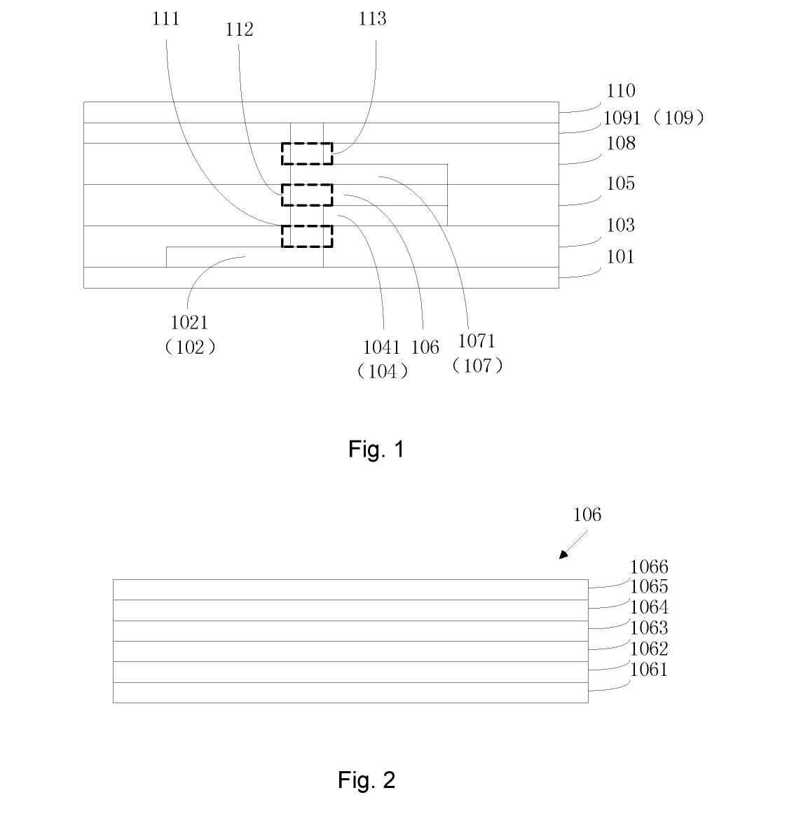

Referring to FIG. 1, a layered structural schematic view of an organic light emitting diode display panel according to a preferred embodiment of this disclosure is shown. The preferred embodiment of the disclosure provides an organic light emitting diode (OLED) display panel, which comprises a substrate 101, and a thin film transistor layer 102, a first insulating layer 103, a first electrode layer 104, a second insulating layer 105, a light emitting layer 106, a second electrode layer 107, a barrier layer 108, an auxiliary electrode layer 109, and a planarization layer 110 laminated on the substrate in sequence.

The substrate 101 may be a rigid substrate or a flexible substrate, and the rigid substrate may preferably be a glass substrate, and the flexible substrate may preferably be a polyimide film. The thin film transistor 102 layer is used to form a plurality of thin film transistors 1021 arranged in an array.

Specifically, the first electrode layer 104 of this disclosure is used to form an anode of an OLED display panel, and comprises a plurality of first electrodes 1041 arranged in an array, each of the first electrodes 1041 corresponds to a pixel of the anode, and each of the first electrodes 1041 is in contact with the corresponding thin film transistor 1021.

It should be noted that a cathode structure of the OLED display panel is collectively formed through the second electrode layer 107 and the auxiliary electrode layer 109, thereby achieving high transparency and high electrical conductivity.

Furthermore, the second electrode layer 107 comprises a plurality of second electrodes 1071 arranged in an array. Each of the first electrodes 1041 and each of the second electrodes 1071 are aligned with each other, and the auxiliary electrode layer 109 comprises rows of auxiliary electrodes 1091, each row of the auxiliary electrodes 1091 is corresponding to and electrically connected with a row of the second electrodes 1071. A cathode of the OLED display panel is collectively formed through a plurality of second electrodes 1071 arranged in an array and a plurality of rows of the auxiliary electrodes 1091.

Referring to FIG. 2, a layered structural schematic view of a light emitting layer is shown. As shown in FIG. 2, the light emitting layer 106 generally includes a hole injection layer 1061, a hole transport layer 1062, a light emitting material layer 1063, a hole blocking layer 1064, an electron transport layer 1065, and an electron injection layer 1066 sequentially laminated. The hole injection layer 1061 is close to the first electrode layer 104, the electron injection layer 1066 is close to the auxiliary electrode layer 109. That is to say, a portion where the light emitting layer 106 is in contact with the first electrode layer 104 is the hole injection layer 1061, and a portion where the light emitting layer 106 is in contact with the electrode layer 109 is the electron injection layer 1066.

In each of pixel limiting regions, a plurality of the light emitting layer 106 are provided for emitting red, green, and blue color light, respectively. The light emitting layer 106 can be one having red, green and blue light emitting materials for emitting color light, respectively.

A positive voltage is applied to the first electrode layer 104, a negative voltage is applied to the auxiliary electrode layer 109, and the light emitting layer 106 can emit light. In general, in a OLED top emission structure, light emitted from the light emitting layer 106 is emitted through the auxiliary electrode layer 109 outwardly. The auxiliary electrode layer 109 is made of a material having high conductivity and high transparency, such as graphene.

Specifically, the first insulating layer 103 is provided with a first through hole 111, the second insulating layer 105 is provided with a second through hole 112, and the barrier layer 108 is provided with a third through hole 113. The first electrode 1041 is in contact with the thin film transistor layer 102 through the first through hole 111. The light emitting layer 106 is in contact with the first electrode 1041 through the second through hole 112 and the auxiliary electrode 1091 is in contact with the second electrode 107 through the third through hole 113.

Moreover, the barrier layer 108 is made of silicon nitride, aluminum oxide or silicon oxide. A thickness of the planarization layer 110 is between 1 μm to 5 μm. The second electrode layer 107 is made of magnesium or silver. A thickness of the second electrode layer 107 is less than 2 nm.

The OLED display panel further comprises at least one encapsulation layer disposed on the planarization layer, and each of the encapsulation layer comprises the barrier layer 108 and the planarization layer 110 that are laminated.

The embodiment relates to the organic light emitting diode display panel. The first electrode layer comprises a plurality of first electrodes arranged in an array. The second electrode layer comprises a plurality of second electrodes arranged in an array. The first electrodes and the second electrodes are aligned with each other. The auxiliary electrode layer comprises rows of auxiliary electrodes, each row of the auxiliary electrodes is corresponding to and electrically connected with a row of the second electrodes, thereby achieving the second electrode matching a work function of an organic material, and at the same time achieving high transparency and conductivity. The auxiliary electrodes can be graphene with high conductivity, high thermal conductivity, thereby effectively improving heat dissipation of the display panel, and reducing the packaging stress.

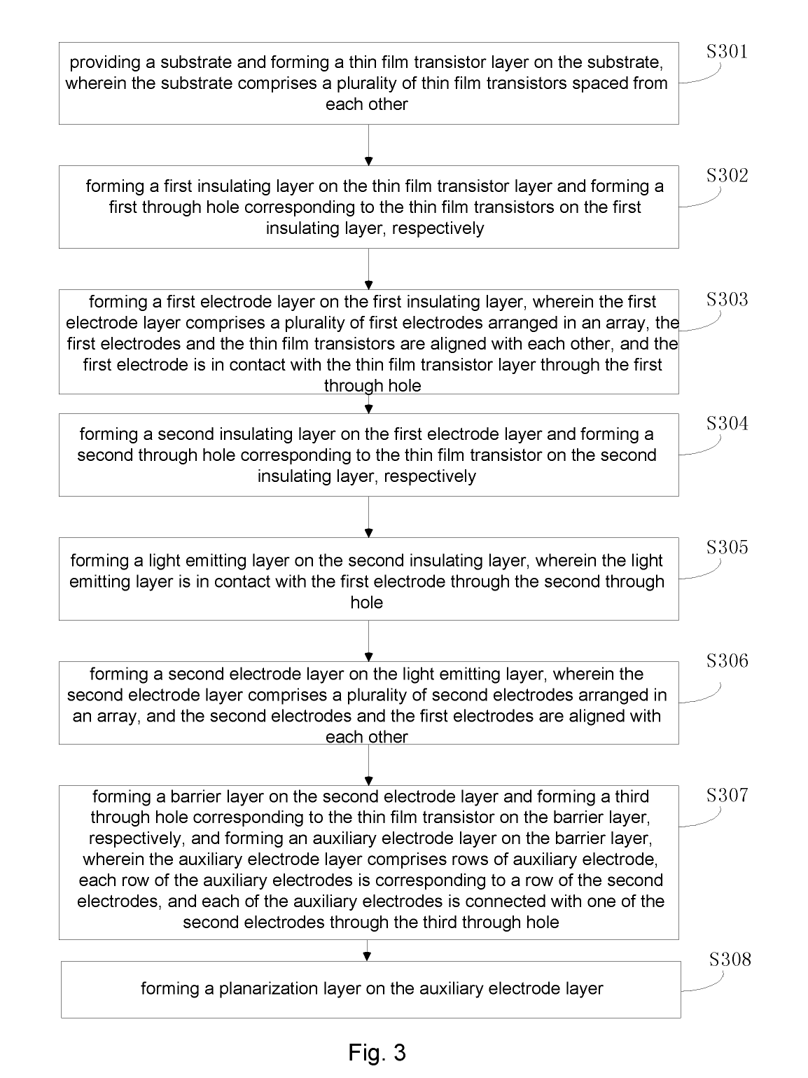

Referring to FIG. 3, a flowchart of a method for manufacturing the organic light emitting diode display panel according to a preferred embodiment of this disclosure is shown. As shown in FIG. 3, method for manufacturing an organic light emitting diode (OLED) display panel comprising the following steps.

In a step S301, providing a substrate and forming a thin film transistor layer on the substrate. The substrate comprises a plurality of thin film transistors spaced from each other.

In a step S302, forming a first insulating layer on the thin film transistor layer and forming a first through hole corresponding to the thin film transistors on the first insulating layer, respectively.

In a step S303, forming a first electrode layer on the first insulating layer. The first electrode layer comprises a plurality of first electrodes arranged in an array. The first electrodes and the thin film transistors are aligned with each other, and the first electrode is in contact with the thin film transistor layer through the first through hole.

In a step S304, forming a second insulating layer on the first electrode layer and forming a second through hole corresponding to the thin film transistor on the second insulating layer, respectively.

In a step S305, forming a light emitting layer on the second insulating layer. The light emitting layer is in contact with the first electrode through the second through hole.

In a step S306, forming a second electrode layer on the light emitting layer. The second electrode layer comprises a plurality of second electrodes arranged in an array, and the second electrodes and the first electrodes are aligned with each other.

In a step S307, forming a barrier layer on the second electrode layer and forming a third through hole corresponding to the thin film transistor on the barrier layer, respectively. An auxiliary electrode layer is formed on the barrier layer. The auxiliary electrode layer comprises rows of auxiliary electrode, each row of the auxiliary electrodes is corresponding to a row of the second electrodes, and each of the auxiliary electrodes is connected with one of the second electrodes through the third through hole.

In a step S308, forming a planarization layer on the auxiliary electrode layer.

Preferably, the auxiliary electrode layer is made of a highly conductive, highly transparent material, such as graphene. The barrier layer is made of silicon nitride, aluminum oxide or silicon oxide. A thickness of the planarization layer is between 1 μm to 5 μm. The second electrode layer is made of magnesium or silver. A thickness of the second electrode layer is less than 2 nm.

Furthermore, after the step of forming the planarization layer on the auxiliary electrode layer, the method further comprises a step of forming at least one encapsulation layer on the planarization layer, wherein each of the encapsulation layer comprises the barrier layer and the planarization layer that are laminated.

This disclosure relates to the organic light emitting diode display panel and the method for manufacturing the organic light emitting diode display panel. The first electrode layer comprises a plurality of first electrodes arranged in an array. The second electrode layer comprises a plurality of second electrodes arranged in an array. The first electrodes and the second electrodes are aligned with each other. The auxiliary electrode layer comprises rows of auxiliary electrodes, each row of the auxiliary electrodes is corresponding to and electrically connected with a row of the second electrodes, thereby achieving the second electrode matching a work function of an organic material, and at the same time achieving high transparency and conductivity. The auxiliary electrodes can be graphene with high conductivity, high thermal conductivity, thereby effectively improving heat dissipation of the display panel, and reducing the packaging stress.

This disclosure has been described with preferred embodiments thereof, and it is understood that many changes and modifications to the described embodiment can be carried out without departing from the scope and the spirit of the invention that is intended to be limited only by the appended claims.

What is claimed is:

1. An organic light emitting diode (OLED) display panel, comprising:
a substrate; and
a thin film transistor layer, a first insulating layer, a first electrode layer, a second insulating layer, a light emitting layer, a second electrode layer, a barrier layer, an auxiliary electrode layer, and a planarization layer arranged on the substrate in sequence;
wherein the first electrode layer comprises a plurality of first electrodes arranged in an array, the second electrode layer comprises a plurality of second electrodes arranged in an array, the first electrodes and the second electrodes are aligned with each other, and the auxiliary electrode layer comprises rows of auxiliary electrodes, each row of the auxiliary electrodes is corresponding to and electrically connected with a row of the second electrodes;
wherein the first insulating layer is provided with a first through hole, the second insulating layer is provided with a second through hole, and the barrier layer is provided with a third through hole;
wherein the first electrode is in contact with the thin film transistor layer through the first through hole, the light emitting layer is in contact with the first electrode through the second through hole, and the auxiliary electrode is in contact with the second electrode through the third through hole; and
wherein a thickness of the second electrode layer is less than 2 nm.

2. The OLED display panel according to claim 1, wherein the auxiliary electrode layer is made of graphene.

3. The OLED display panel according to claim 1, wherein the barrier layer is made of silicon nitride, aluminum oxide or silicon oxide.

4. The OLED display panel according to claim 1, wherein a thickness of the planarization layer is between 1 μm to 5 μm.

5. The OLED display panel according to claim 1, wherein the second electrode layer is made of magnesium or silver.

6. The OLED display panel according to claim 1, wherein the OLED display panel further comprises at least one encapsulation layer disposed on the planarization layer, and each of the encapsulation layer comprises the barrier layer and the planarization layer that are laminated.

7. An organic light emitting diode (OLED) display panel, comprising:
a substrate; and
a thin film transistor layer, a first insulating layer, a first electrode layer, a second insulating layer, a light emitting layer, a second electrode layer, a barrier layer, an auxiliary electrode layer, and a planarization layer arranged on the substrate in sequence;
wherein the first electrode layer comprises a plurality of first electrodes arranged in an array, the second electrode layer comprises a plurality of second electrodes arranged in an array, the first electrodes and the second electrodes are aligned with each other, and the auxiliary electrode layer comprises rows of auxiliary electrodes, each row of the auxiliary electrodes is corresponding to and electrically connected with a row of the second electrodes.

8. The OLED display panel according to claim 7, wherein the first insulating layer is provided with a first through hole, the second insulating layer is provided with a second through hole, and the barrier layer is provided with a third through hole and
wherein the first electrode is in contact with the thin film transistor layer through the first through hole, the light emitting layer is in contact with the first electrode through the second through hole, and the auxiliary electrode is in contact with the second electrode through the third through hole.

9. The OLED display panel according to claim 7, wherein the auxiliary electrode layer is made of graphene.

10. The OLED display panel according to claim 7, wherein the barrier layer is made of silicon nitride, aluminum oxide or silicon oxide.

11. The OLED display panel according to claim 7, wherein a thickness of the planarization layer is between 1 μm to 5 μm.

12. The OLED display panel according to claim 7, wherein the second electrode layer is made of magnesium or silver.

13. The OLED display panel according to claim 7, wherein a thickness of the second electrode layer is less than 2 nm.

14. The OLED display panel according to claim 12, wherein a thickness of the second electrode layer is less than 2 nm.

15. The OLED display panel according to claim 7, wherein the OLED display panel further comprises at least one encapsulation layer disposed on the planarization layer, and each of the encapsulation layer comprises the barrier layer and the planarization layer that are laminated.

16. A method for manufacturing an organic light emitting diode (OLED) display panel, comprising steps of:
providing a substrate and forming a thin film transistor layer on the substrate, wherein the substrate comprises a plurality of thin film transistors spaced from each other;
forming a first insulating layer on the thin film transistor layer and forming a first through hole corresponding to the thin film transistors on the first insulating layer, respectively;
forming a first electrode layer on the first insulating layer, wherein the first electrode layer comprises a plurality of first electrodes arranged in an array, the first electrodes and the thin film transistors are aligned with each other, and the first electrode is in contact with the thin film transistor layer through the first through hole;
forming a second insulating layer on the first electrode layer and forming a second through hole corresponding to the thin film transistor on the second insulating layer, respectively;
forming a light emitting layer on the second insulating layer, wherein the light emitting layer is in contact with the first electrode through the second through hole;
forming a second electrode layer on the light emitting layer, wherein the second electrode layer comprises a plurality of second electrodes arranged in an array, and the second electrodes and the first electrodes are aligned with each other;
forming a barrier layer on the second electrode layer and forming a third through hole corresponding to the thin film transistor on the barrier layer, respectively;
forming an auxiliary electrode layer on the barrier layer, wherein the auxiliary electrode layer comprises rows of auxiliary electrode, each row of the auxiliary electrodes is corresponding to a row of the second electrodes, and each of the auxiliary electrodes is connected with one of the second electrodes through the third through hole; and
forming a planarization layer on the auxiliary electrode layer.

17. The method for manufacturing an OLED display panel according to claim 16, wherein after the step of forming the planarization layer on the auxiliary electrode layer, the method further comprises a step of forming at least one encapsulation layer on the planarization layer, wherein each of the encapsulation layer comprises the barrier layer and the planarization layer that are laminated.
